(19) United States
(12) Patent Application Publication
(10) Pub. No.: US 2025/0216470 A1
(43) Pub. Date: Jul. 3, 2025

(54) BATTERY ANALYSIS SYSTEM, BATTERY ANALYSIS METHOD, AND NON-TRANSITORY COMPUTER-READABLE RECORDING MEDIUM

(71) Applicant: Panasonic Intellectual Property Management Co., Ltd., Osaka (JP)

(72) Inventor: Shigeru MATSUDA, Osaka (JP)

(21) Appl. No.: 18/851,219

(22) PCT Filed: Jan. 30, 2023
(86) PCT No.: PCT/JP2023/002824

§ 371 Date: Sep. 26, 2024

(30) Foreign Application Priority Data
Mar. 30, 2022 (JP) 2022-056433

(51) Int. Cl. G01R 31/388; G01R 31/367; G01R 31/389; G01R 31/392; G01R 31/396; H01M 10/42

(52) U.S. Cl. CPC G01R 31/388; G01R 31/367; G01R 31/389; G01R 31/392; G01R 31/396; H01M 10/4285

(57) ABSTRACT

A battery-specific characteristic generation unit estimates, for each battery pack, an SOC (State of Charge)-OCV (Open Circuit Voltage) curve of a cell block included in the battery pack, a resistance of the cell block, and a capacity of the cell block, and calculates a resistance capacity product derived from multiplying the resistance of the cell block by the capacity of the cell block. A cell type identification unit identifies a type of the cell included in an undefined battery pack based on a degree of agreement between the SOC-OCV curve of the cell block of the undefined battery pack and the SOC-OCV curve of an already-defined cell block and based on a degree of agreement between the resistance capacity product of the cell block of the undefined battery pack and the resistance capacity product of the already-defined cell block.

### CROSS-REFERENCE TO RELATED APPLICATIONS

This application is the U.S. National Phase under 35 U.S.C. § 371 of International Application No. PCT/JP2023/002824, filed on Jan. 30, 2023, which claims the benefit of foreign priority to Japan Patent Application No. 2022-056433, filed on Mar. 30, 2022, the entire contents of each of which are hereby incorporated by reference.

### BACKGROUND

### Field of the Invention

The present disclosure relates to a battery analysis system, a battery analysis method, and a battery analysis program for analyzing the performance of a cell included in a battery pack.

### Description of the Related Art

Products equipped with batteries may not meet the performance expected from the catalog specification (battery capacity, etc.). In EVs equipped with battery packs including iron phosphate lithium-ion batteries, for example, cases have arisen where a cruising distance shorter than what it should be is displayed in winter. The above problem can be avoided if the actual performance or defects of the product are known before purchase, but the problem is revealed only after the product is put into operation for some time after purchase.

If the cell type (it means “model number” here) of an unknown battery-equipped product can be identified, and if battery characteristic data for that cell type under various conditions (early/midterm/later in the term of operation, low/medium/high temperature, etc.) is available, it should be possible to predict the performance of that battery-equipped product under various conditions without a long-term operation. When an EV is purchased, for example, the performance at the end of life or at low temperature can be grasped and put to use to make a purchase decision only by referring to the battery characteristic data that can be acquired when the vehicle is test-driven.

Patent Literature 1 is a related art relevant to the present disclosure and discloses a method for improving the efficiency of battery characteristic estimation by identifying a battery cell or a battery pack. However, identification is based on prior knowledge, and it is not possible to identify an unknown battery cell or battery pack. Patent Literature 2 discloses a method for identifying a battery pack but requires a special circuit configuration.
Patent Literature 1: JP2021-180158
Patent Literature 2: JP2001-283934

### SUMMARY OF THE INVENTION

The present disclosure addresses the issue described above, and a purpose thereof is to provide a technology for identifying the type of an unknown cell based on battery data.

A battery analysis system according to an embodiment of the present disclosure includes: a data acquisition unit that acquires battery data including i) a voltage of at least one cell block included in a battery pack including cell blocks connected in series, the cell block being comprised of one or more cells connected in parallel and ii) a current flowing in a plurality of cell blocks connected in series; a battery-specific characteristic generation unit that estimates, for each battery pack, an SOC (State of Charge)-OCV (Open Circuit Voltage) curve of a cell block included in the battery pack, a resistance of the cell block, and a capacity of the cell block, and calculates a resistance capacity product derived from multiplying the resistance of the cell block by the capacity of the cell block; and a cell type identification unit that identifies a type of the cell included in an undefined battery pack based on a degree of agreement between the SOC-OCV curve of the cell block of the undefined battery pack and the SOC-OCV curve of an already-defined cell block and based on a degree of agreement between the resistance capacity product of the cell block of the undefined battery pack and the resistance capacity product of the already-defined cell block.

Optional combinations of the aforementioned constituting elements, and implementations of the present disclosure in the form of apparatuses, systems, methods, and computer programs are also useful as embodiments of the present disclosure.

Embodiments will now be described, by way of example only, with reference to the accompanying drawings which are meant to be exemplary, not limiting, and wherein like elements are numbered alike in several Figures, in which:

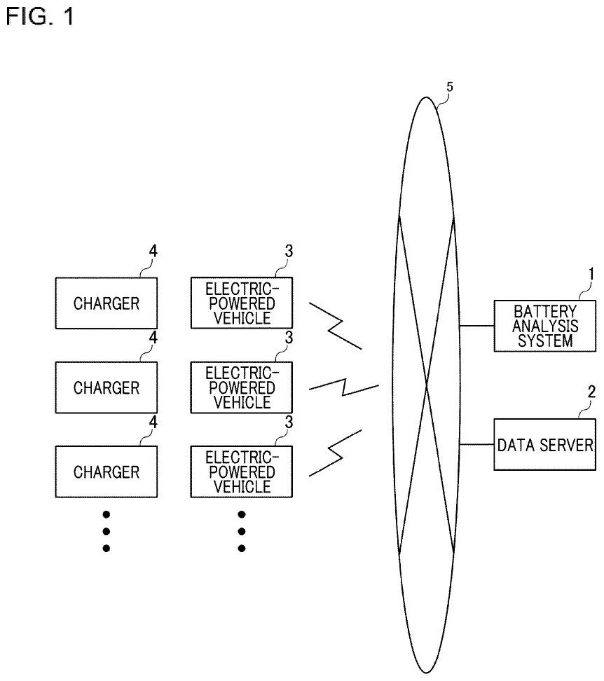

FIG. 1 is a diagram for illustrating a battery analysis system according to the embodiment.

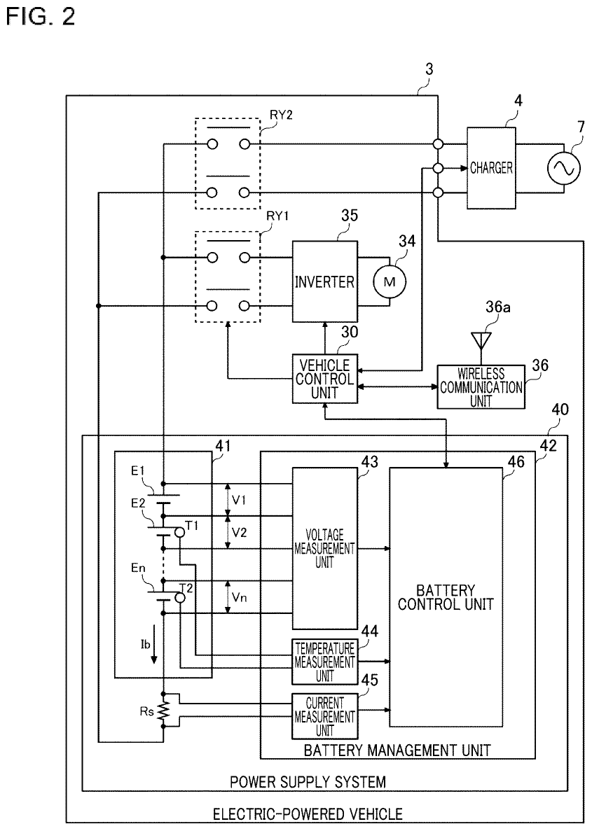

FIG. 2 is a diagram for illustrating a detailed configuration of a power supply system mounted on the electric-powered vehicle.

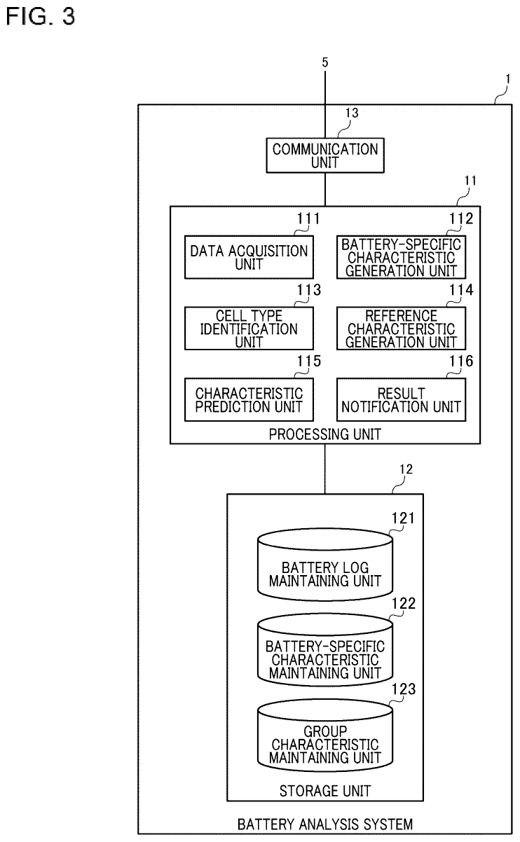

FIG. 3 is a diagram showing an exemplary configuration of the battery analysis system according to the embodiment.

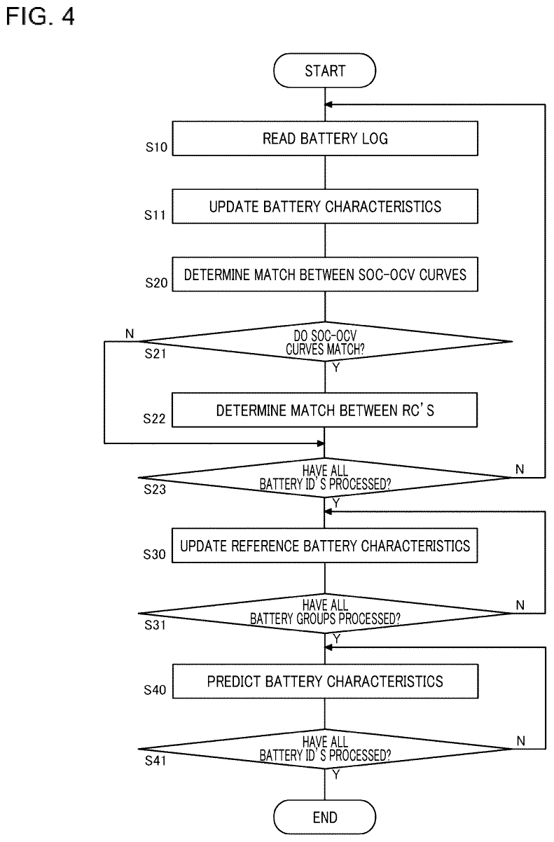

FIG. 4 is a flowchart showing a schematic operation of the battery analysis system according to the embodiment.

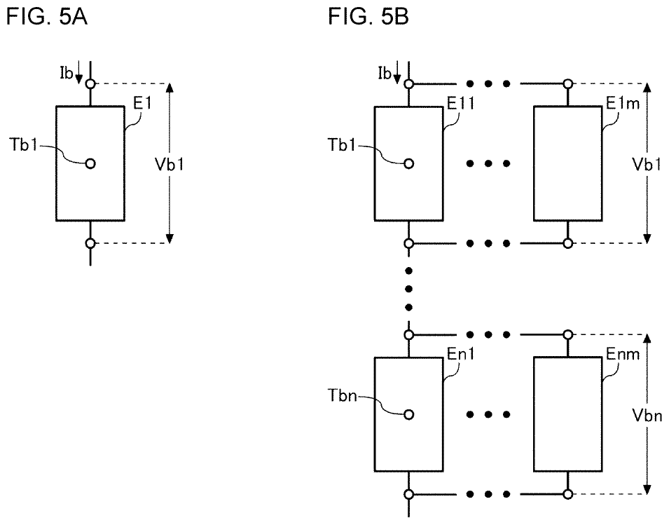

FIGS. 5A-5B are diagrams for illustrating a battery log collection step.

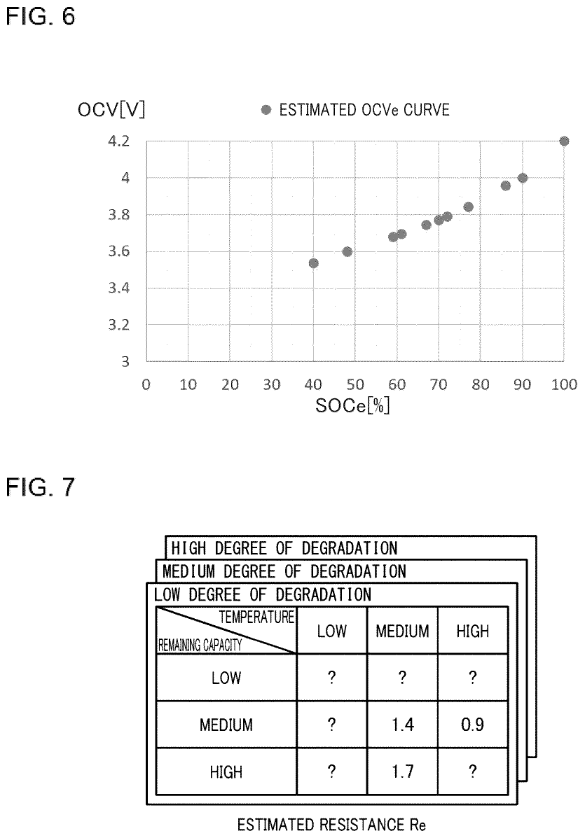

FIG. 6 is a diagram showing a calculated example of the estimated OCVe curve.

FIG. 7 is a diagram showing examples of the estimated resistance Re calculated under each condition.

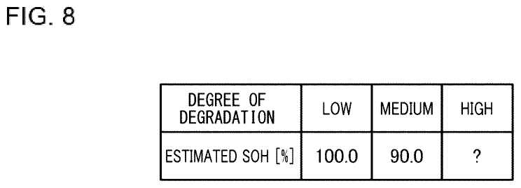

FIG. 8 is a diagram showing examples of the estimated SOHe calculated at each degree of degradation.

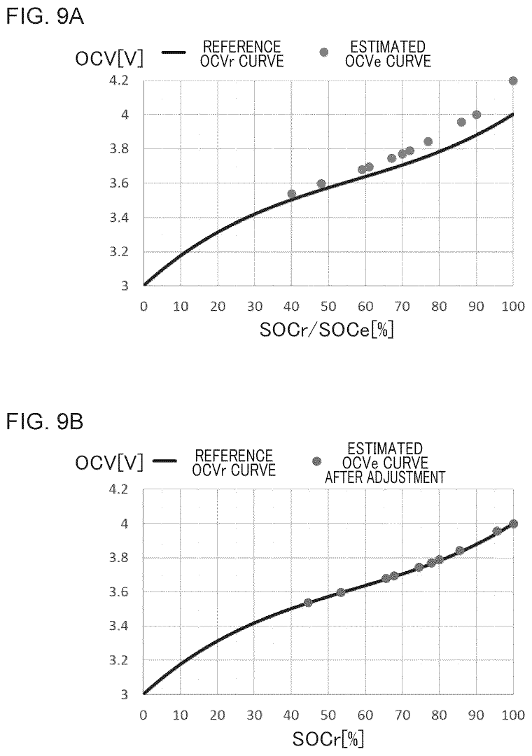

FIGS. 9A-9B are diagrams showing the reference OCVr curve and a calculated example of the estimated OCVe curve superimposed on graphs.

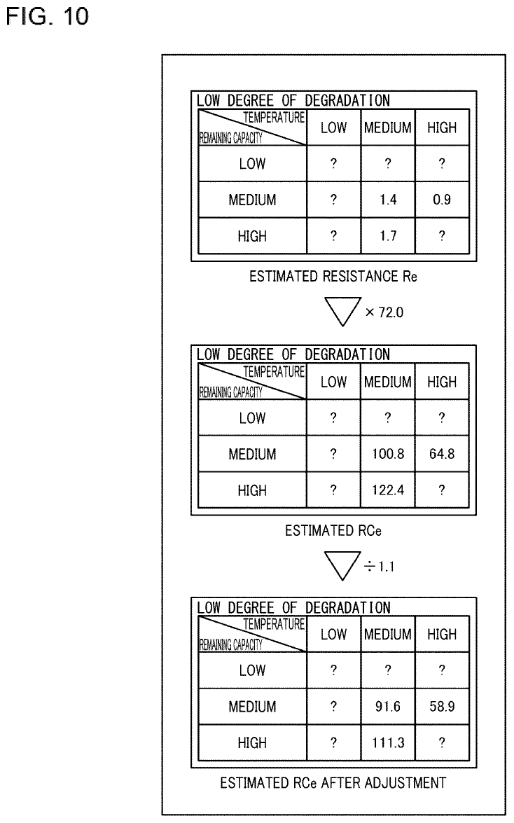

FIG. 10 is a diagram showing calculated examples of the estimated resistance Re, the estimated RCe, and the estimated RCe after adjustment at “low” degree of degradation.

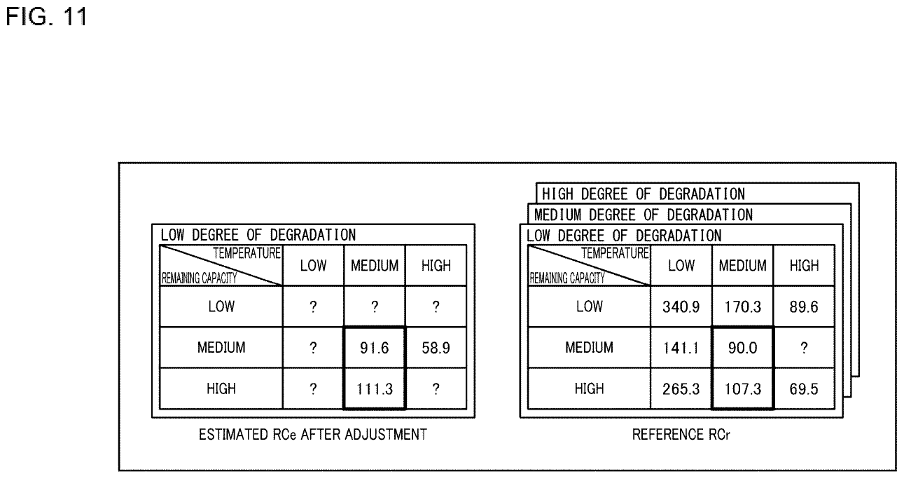

FIG. 11 is a diagram showing calculated examples of the estimated RCe and the reference RCr after adjustment at “low” degree of degradation.

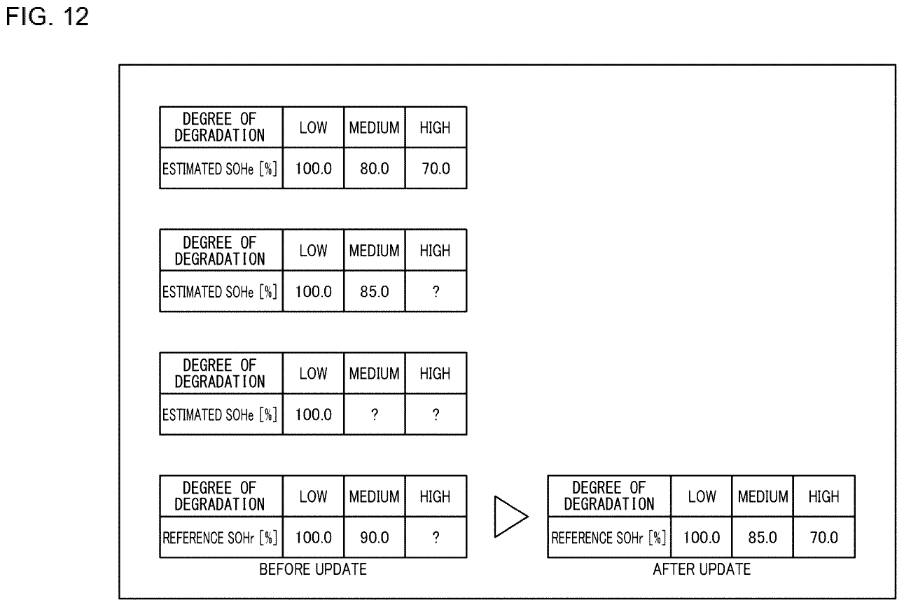

FIG. 12 is a diagram showing an example of updating the reference SOHr.

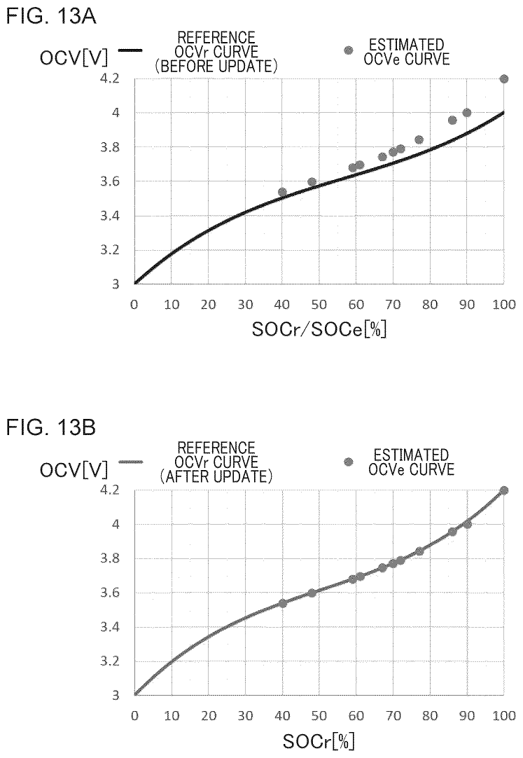

FIGS. 13A-13B are diagrams showing the reference OCVr curve and a calculated example of the estimated OCVe curve superimposed on graphs.

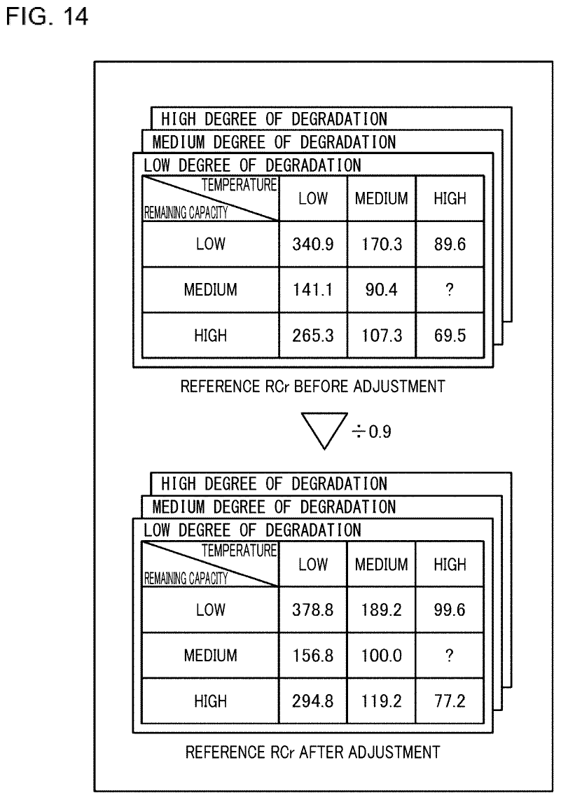

FIG. 14 is a diagram showing calculated examples of the estimated RCe before adjustment and the estimated RCe after adjustment.

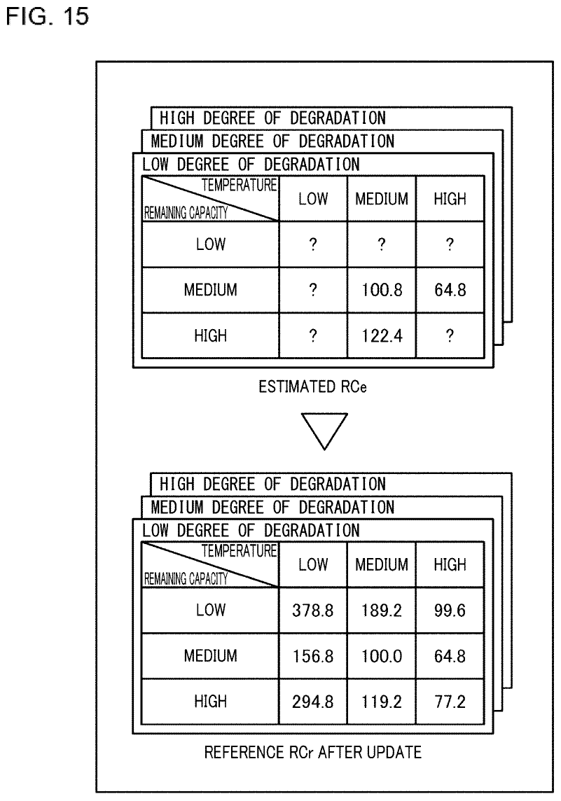

FIG. 15 is a diagram showing calculated examples of the estimated RCe and the reference RCr after an update.

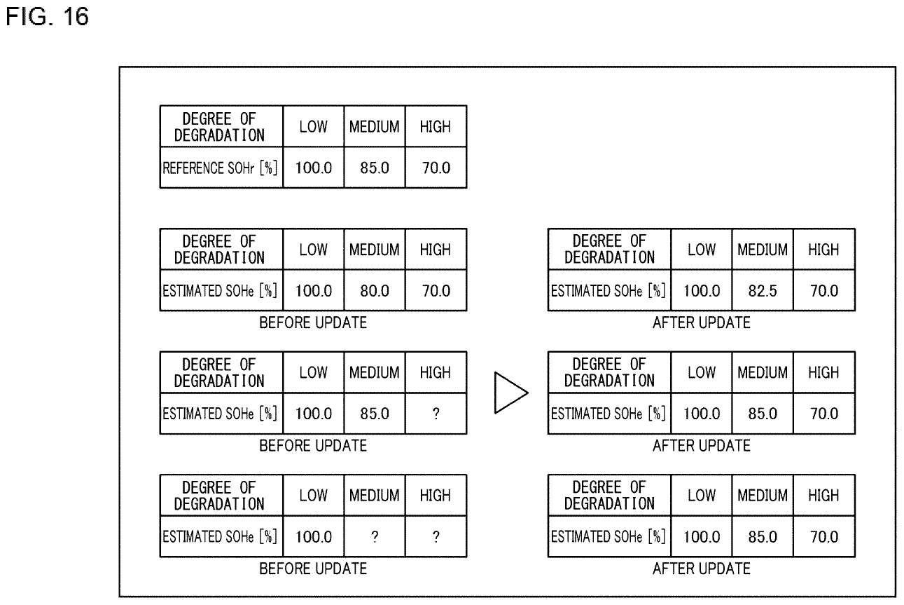

FIG. 16 is a diagram showing an example of updating the estimated SOHe.

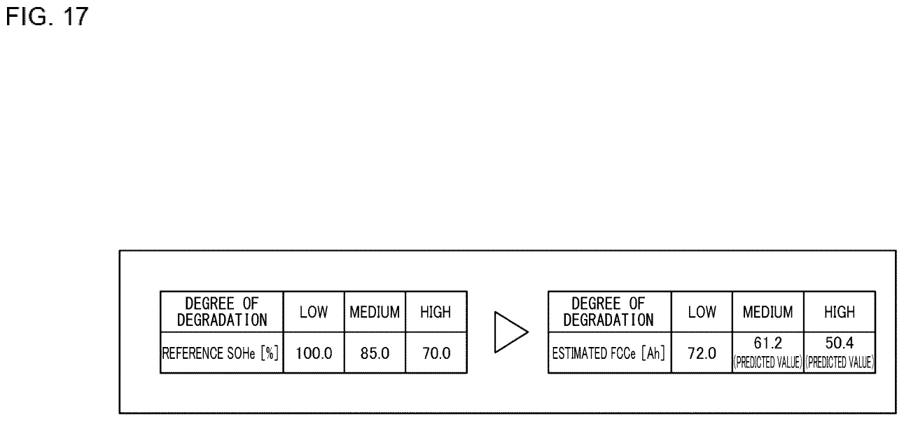

FIG. 17 is a diagram showing an example of predicting the estimated FCCe.

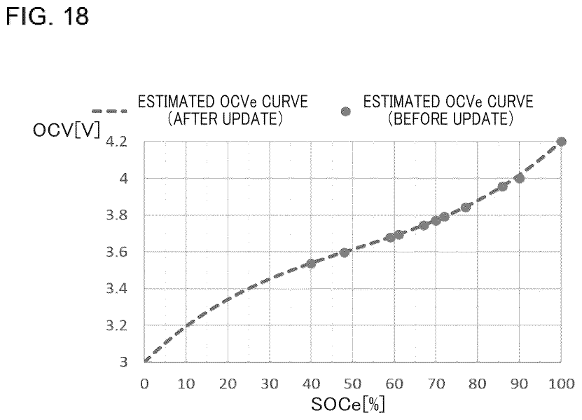

FIG. 18 is a diagram showing calculated examples of the estimated OCVe curve before the update and the estimated OCVe curve after the update superimposed on a graph.

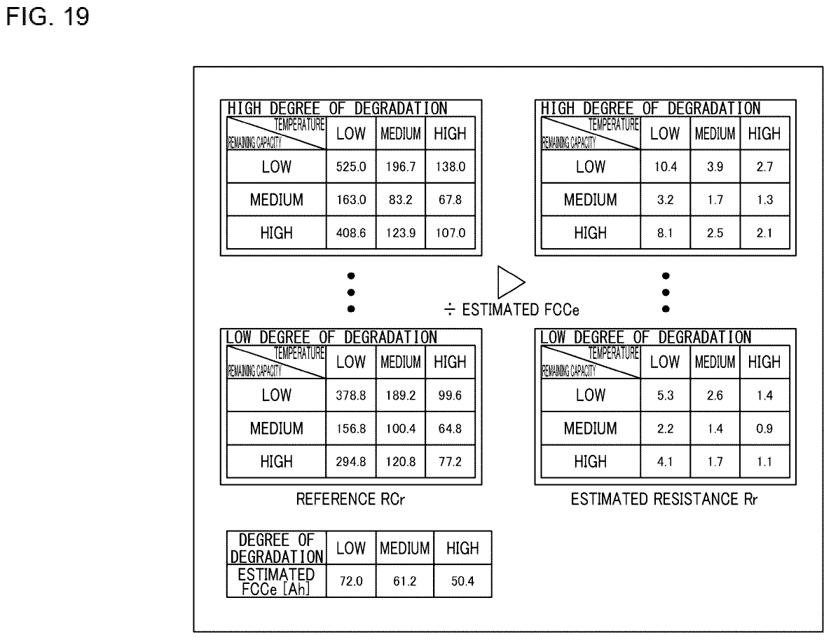

FIG. 19 is a diagram showing calculated examples of the reference RCr and the reference resistance Rr.

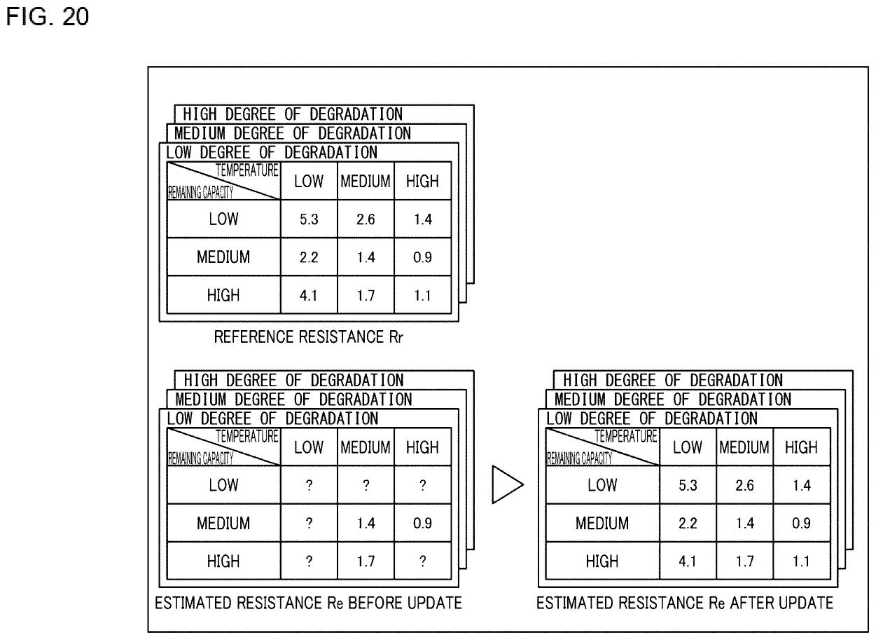

FIG. 20 is a diagram showing an example of updating the estimated resistor Re.

### DETAILED DESCRIPTION OF THE INVENTION

The invention will now be described by reference to the preferred embodiments. This does not intend to limit the scope of the present invention, but to exemplify the invention.

FIG. 1 is a diagram for illustrating a battery analysis system 1 according to the embodiment. The battery analysis system 1 according to the embodiment has a function of predicting the characteristics of a cell included in a battery pack. The battery analysis system 1 according to the embodiment is a system used by an individual or a corporation considering the purchase of an electric-powered vehicle 3 or using the electric-powered vehicle 3. For example, it is also used by a corporation that owns a plurality of electric-powered vehicles 3 and uses the plurality of electric-powered vehicles 3 for a rental business, a sharing business, or a delivery business.

The battery analysis system 1 may, for example, be built on an in-house server provided in an in-house facility of a service provider that provides a battery analysis service or provided in a data center. Alternatively, the battery analysis system 1 may be built on a cloud server that is used based on a cloud service contract. Alternatively, the battery analysis system 1 may be built on a plurality of servers distributed at a plurality of sites (data centers, in-house facilities). The plurality of servers may be any of a combination of a plurality of in-house servers, a combination of a plurality of cloud servers, or a combination of an in-house server and a cloud server.

The electric-powered vehicle 3 has a communication function, can be connected to a network 5. The electric-powered vehicle 3 transmits battery data to a data server 2 via the network 5. The system may be configured to include the data server 2 and the battery analysis system 1 integrated with each other. The electric-powered vehicle 3 periodically (for example, every 10 seconds) samples battery data and transmits the sampled battery data in real time. Alternatively, the electric-powered vehicle 3 stores the battery data in an internal memory temporarily and transmits the data in batches at a predetermined point of time.

When the electric-powered vehicle 3 is test-driven, the prospective purchaser or the purchasing representative may connect a TCU (Telematics Control Unit) equipped with a communication module to the OBD2 (On Board Diagnosis second generation) connector provided in the vehicle to transmit the battery data from the TCU to the data server 2. Alternatively, the prospective purchaser, etc. may receive the battery data for the electric-powered vehicle 3 from a dealer or a sales outlet. The prospective purchaser, etc. may input the battery data to an information terminal (e.g., a PC or a smartphone) managed by the prospective purchaser, etc. and transmit the battery data from the information terminal to the data server 2.

The data server 2 collects and stores the battery data from the electric-powered vehicle 3 or an external information terminal. The data server 2 may be an in-house server provided in an in-house facility of a battery analysis service provider or a service provider owning a plurality of electric-powered vehicles 3 or provided in a data center. The data server 2 may alternatively be a cloud server used by the battery analysis service provider or the service provider owning a plurality of electric-powered vehicles 3. Further, the both may have data server 2 each.

The network 5 is a general term for communication channels such as the Internet, leased lines, and VPN (Virtual Private Network), and the communication medium and the protocol thereof do not matter. For example, a mobile phone network (cellular network), a wireless LAN, a wired LAN, an optical fiber network, an ADSL network, a CATV network, and the like can be used as the communication medium. For example, TCP (Transmission Control Protocol)/IP (Internet Protocol), UDP (User Datagram Protocol)/IP, Ethernet (registered trademark) and the like can be used as the communication protocol.

FIG. 2 is a diagram for illustrating a detailed configuration of a power supply system 40 mounted on the electric-powered vehicle 3. The power supply system 40 is connected to a motor 34 via a first relay RY1 and an inverter 35. The inverter 35 converts a DC power supplied from the power supply system 40 into an AC power and supplies it to the motor 34 during power running. During regeneration, the inverter 35 converts the AC power supplied from the motor 34 into a DC power and supplies it to the power supply system 40. The motor 34 is a three-phase AC motor and rotates according to the AC power supplied from the inverter 35 during power running. During regeneration, the motor 34 converts the rotational energy caused by deceleration into an AC power and supplies it to the inverter 35.

A vehicle control unit 30 is a vehicle ECU (Electronic Control Unit) that controls the entire electric-powered vehicle 3 and may be, for example, comprised of an integrated VCM (Vehicle Control Module). A wireless communication unit 36 has a modem and performs a wireless signal process for wireless connection to the network 5 via an antenna 36a. Examples of wireless communication networks to which the electric-powered vehicle 3 can be wirelessly connected include a mobile phone network (cellular network), a wireless LAN, V2I (Vehicle-to-Infrastructure), V2 V (Vehicle-to-Vehicle), ETC system (Electronic Toll Collection System), and DSRC (Dedicated Short Range Communications).

The first relay RY1 is a contactor inserted between the wirings connecting the power supply system 40 and the inverter 35. The vehicle control unit 30 controls the first relay RY1 to be on (closed state) while the vehicle is running to electrically connect the power supply system 40 and the power system of the electric-powered vehicle 3. While the vehicle is not running, the vehicle control unit 30 controls the first relay RY1 to be off (open state) in principle and electrically cuts off the power supply system 40 and the power system of the electric-powered vehicle 3 from each other. Instead of a relay, a different type of switch such as a semiconductor switch may be used.

The electric-powered vehicle 3 is adapted to charge a battery pack 41 in the power supply system 40 from outside by being connected to a charger 4. The charger 4 is connected to a commercial power system 7 and charges the battery pack 41 in the electric-powered vehicle 3. In the electric-powered vehicle 3, a second relay RY2 is inserted between the wirings connecting the power supply system 40 and the charger 4. Instead of a relay, a different type of switch such as a semiconductor switch may be used. A battery management unit 42 controls the second relay RY2 to be on via the vehicle control unit 30 or directly before charging is started and controls the second relay RY2 to be off after charging is completed.

In general, a battery is charged with AC in the case of normal charging and is charged with DC in the case of fast charging. In the case of charging the battery with AC (for example, single-phase 100/200 V), the AC power is converted into a DC power by an AC/DC converter (not shown) inserted between the second relay RY2 and the battery pack 41. In the case of charging the battery with DC, the charger 4 generates the DC power by rectifying the AC power supplied from the commercial power system 7 in full wave rectification and smoothing the power with a filter.

Examples of fast charging standards that can be used include CHAdeMO (registered trademark), ChaoJi, GB/T, Combo (Combined Charging System). CHAdeMO2.0 stipulates that the maximum output (specification) is 1000 V×400 A=400 kW. CHAdeMO3.0 stipulates that the maximum output (specification) is 1500 V×600 A=900 kW. ChaoJi stipulates that the maximum output (specification) is 1500 V×600 A=900 kW. GB/T stipulates that the maximum output (specification) is 750 V×250 A=185 kW. Combo stipulates that the maximum output (specification) is 900 V×400 A=350 KW. CHAdeMO, ChaoJi, and GB/T use CAN (Controller Area Network) as the communication method. Combo uses PLC (Power Line Communication) as the communication method.

In addition to power lines, communication lines are also included in the charging cable in which the CAN scheme is employed. When the electric-powered vehicle 3 and the charger 4 are connected by the charging cable, the vehicle control unit 30 establishes a communication channel with the control unit in the charger 4. In the charging cable in which the PLC scheme is employed, a communication signal is superimposed and transmitted on the power line.

The vehicle control unit 30 establishes a communication channel with the battery management unit 42 via a vehicle-mounted network (for example, CAN or LIN (Local Interconnect Network)). When the communication standard between the vehicle control unit 30 and the control unit in the charger 4 and the communication standard between the vehicle control unit 30 and the battery management unit 42 are different, the vehicle control unit 30 performs a gateway function.

The power supply system 40 mounted on the electric-powered vehicle 3 includes the battery pack 41 and the battery management unit 42. The battery pack 41 includes a plurality of cells E1-En or a plurality of parallel cell blocks. A parallel cell block is comprised of a plurality of cells connected in parallel. Hereinafter, a single cell and a parallel cell block will be generically denoted as a cell block in this specification. In other words, a cell block is comprised of one or more cells connected in parallel. A lithium ion battery cell, a nickel hydride battery cell, a lead battery cell or the like can be used as the cell. Hereinafter, an example of using a lithium ion battery cell (nominal voltage: 3.6-3.7 V) is assumed in this specification. The number of cell blocks connected in series is determined according to the drive voltage of the motor 34.

A shunt resistor Rs is connected in series with the plurality of cell blocks. The shunt resistor Rs functions as a current-sensing element. A Hall element may be used instead of the shunt resistor Rs. A plurality of temperature sensors T1, T2 for detecting the temperature of the plurality of cell blocks are provided in the battery pack 41. For example, a thermistor can be used as the temperature sensors T1, T2.

The battery management unit 42 includes a voltage measurement unit 43, a temperature measurement unit 44, a current measurement unit 45, and a battery control unit 46. The nodes of the plurality of cell blocks connected in series and the voltage measurement unit 43 are connected by a plurality of voltage lines. The voltage measurement unit 43 measures the voltage V1-Vn of each cell block by measuring the voltage between two adjacent voltage lines respectively. The voltage measurement unit 43 transmits the voltage V1-Vn of each cell block thus measured to the battery control unit 46.

Since the voltage measurement unit 43 is at a higher voltage than the battery control unit 46, the voltage measurement unit 43 and the battery control unit 46 are connected by a communication line in an electrically insulated state. The voltage measurement unit 43 can be comprised of an ASIC (Application Specific Integrated Circuit) or a general-purpose analog front-end IC. The voltage measurement unit 43 includes a multiplexer and an A/D converter. The multiplexer successively outputs the voltage between two adjacent voltage lines to the A/D converter from top to bottom. The A/D converter converts the analog voltage input from the multiplexer into a digital value.

The temperature measurement unit 44 includes a voltage divider resistor and an A/D converter. The A/D converter converts a plurality of analog voltages divided by the plurality of temperature sensors T1, T2 and the plurality of voltage divider resistors into digital values successively and outputs them to the battery control unit 46. The battery control unit 46 measures the temperature at a plurality of observation points in the battery pack 41 based on the plurality of digital values.

The current measurement unit 45 includes a differential amplifier and an A/D converter. The differential amplifier amplifies the voltage across the shunt resistor Rs and outputs the amplified voltage to the A/D converter. The A/D converter converts the analog voltage input from the differential amplifier into a digital value and outputs it to the battery control unit 46. The battery control unit 46 measures a current Ib flowing through the plurality of cell blocks based on the digital value.

In the case an A/D converter is mounted in the battery control unit 46 and an analog input port is provided in the battery control unit 46, the temperature measurement unit 44 and the current measurement unit 45 may output an analog voltage to the battery control unit 46, and the A/D converter in the battery control unit 46 may convert the analog voltage into a digital value.

The battery control unit 46 manages the state of the plurality of cell blocks based on the voltage, temperature, and current of the plurality of cell blocks measured by the voltage measurement unit 43, the temperature measurement unit 44, and the current measurement unit 45. When an overvoltage, undervoltage, overcurrent, or temperature abnormality occurs in at least one of the plurality of cell blocks, the battery control unit 46 turns off the second relay RY2 or the protection relay (not shown) in the battery pack 41 to protect the cell block.

The battery control unit 46 can be comprised of a microcontroller and a non-volatile memory (e.g., EEPROM (Electrically Erasable Programmable Read-Only Memory), flash memory). The battery control unit 46 estimates the SOC (State Of Charge) of each of the plurality of cell blocks.

The battery control unit 46 estimates SOC by combining the OCV (Open Circuit Voltage) method and the current integration method. The OCV method is a method of estimating SOC based on the OCV of each cell block measured by the voltage measurement unit 43 and the SOC-OCV curve of the cell block. The SOC-OCV curve of the cell block is created in advance based on a characteristic test by the battery manufacturer and is registered in the internal memory of the microcontroller at the time of shipment.

The current accumulation method is a method of estimating SOC based on the OCV at the start of charging or discharging of each cell block and the integrated value of the current measured by the current measurement unit 45. In the current accumulation method, the measurement error of the current measurement unit 45 accumulates as the charging/discharging time increases. On the other hand, the OCV method is affected by the measurement error of the voltage measurement unit 43 and the error caused by the polarization voltage. It is therefore preferable to use a weighted average of the SOC estimated by the current accumulation method and the SOC estimated by the OCV method.

The battery control unit 46 periodically (for example, every 10 seconds) samples battery data including voltage, current, temperature, and SOC of each cell block and transmits the data to the vehicle control unit 30 via the vehicle-mounted network. In the case the number of cell blocks connected in series is large, the battery control unit 46 may transmit, as voltage data, only the representative value (e.g., median, average value, or maximum value and minimum value) of the plurality of cell blocks to the vehicle control unit 30. Further, in the case the number of temperature sensors provided in the battery pack 41 is large, the battery control unit 46 may transmit, as temperature data, only a representative value (e.g., median, average value, or maximum temperature and minimum temperature) in the battery pack 41 to the vehicle control unit 30.

The vehicle control unit 30 can transmit battery data to the data server 2 in real time using the wireless communication unit 36 while the electric-powered vehicle 3 is running. Alternatively, the vehicle control unit 30 may store the battery data for the electric-powered vehicle 3 in the internal memory and collectively transmit the battery data stored in the memory at a predetermined point of time. For example, the vehicle control unit 30 may be started periodically while the electric-powered vehicle 3 is being parked and may use the wireless communication unit 36 to collectively transmit the battery data stored in the memory to the data server 2.

Alternatively, the vehicle control unit 30 may collectively transmit the battery data stored in the memory to the operation management terminal apparatus provided in a business facility at the end of the day's business. The operation management terminal apparatus collectively transmits the battery data for the plurality of electric-powered vehicles 3 to the data server 2 at a predetermined point of time. Alternatively, the vehicle control unit 30 may collectively transmit the battery data stored in the memory to the charger 4 having a network communication function via the charging cable when the battery is charged by the charger 4. The charger 4 having a network communication function transmits the received battery data to the data server 2. This example is useful for the electric-powered vehicle 3 not equipped with a wireless communication function.

FIG. 3 is a diagram showing an exemplary configuration of the battery analysis system 1 according to the embodiment. The battery analysis system 1 includes a processing unit 11, a storage unit 12, and a communication unit 13. The communication unit 13 is a communication interface (for example, NIC: Network Interface Card) for connecting to the network 5 by wire or wirelessly.

The processing unit 11 includes a data acquisition unit 111, a battery-specific characteristic generation unit 112, a cell type identification unit 113, a reference characteristic generation unit 114, a characteristic prediction unit 115, and a result notification unit 116. The function of the processing unit 11 can be realized by cooperation between hardware resources and software resources or by hardware resources alone. Hardware resources such as CPU, ROM, RAM, GPU (Graphics Processing Unit), ASIC (Application Specific Integrated Circuit), FPGA (Field Programmable Gate Array), and other LSIs can be used. Programs such as operating systems and applications can be used as software resources.

The storage unit 12 includes a battery log maintaining unit 121, a battery-specific characteristic maintaining unit 122, and a group characteristic maintaining unit 123. The storage unit 12 is inclusive of a non-volatile recording medium such as a HDD and an SSD and stores various data. The battery log maintaining unit 121 maintains a battery log for each single cell or battery pack 41. The battery log includes a block current, block voltage, block temperature, and estimated SOC sampled at each point of time.

The battery-specific characteristic maintaining unit 122 maintains, for each battery ID, a battery group, an estimated SOC-OCV curve, an estimated resistance, an estimated FCC (Full Charge Capacity), an estimated SOH (State Of Health), and the first SOC coefficient. The group characteristic maintaining unit 123 maintains, for each battery group, a reference SOC-OCV curve, a reference RC, and a reference SOH. The specific detail of each parameter will be described later.

The data acquisition unit 111 acquires battery data for the battery pack 41 mounted on the electric-powered vehicle 3 from the data server 2 and registers the data in the battery log maintaining unit 121. The data acquisition unit 111 reads, for each battery ID, battery data (block current, block voltage, block temperature, estimated SOC) sampled at each point of time from the battery log maintaining unit 121 at a point of time when the battery characteristic is updated.

The battery-specific characteristic generation unit 112 estimates, for each battery ID, the SOC-OCV curve of the cell block, the resistance of the cell block, the capacity of the cell block (more specifically, FCC), and the SOH of the cell block. The battery-specific characteristic generation unit 112 calculates, for each battery ID, a resistance capacity product (hereinafter referred to as RC) by multiplying the resistance of the cell block and the capacity of the cell block. The battery-specific characteristic generation unit 112 generates the RC of the cell block for each of a plurality of classes derived from classification with reference to at least one of degree of degradation or temperature. The specific method of calculating each parameter will be described later.

The battery-specific characteristic generation unit 112 registers the estimated SOC-OCV curve of the cell block, the estimated resistance of the cell block, the estimated FCC of the cell block, and the estimated SOH of the cell block generated for each battery ID in the battery-specific characteristic maintaining unit 122.

The reference characteristic generation unit 114 generates a reference SOC-OCV curve, a reference RC, and a reference SOH for each battery group based on a plurality of SOC-OCV curves, a plurality of RCs, and a plurality of SOHs of a plurality of cell blocks including cells of the same type. The reference characteristic generation unit 114 generates the reference RC for each of a plurality of classes derived from classification with reference to at least one of degree of degradation or temperature. The specific method of calculating each parameter will be described later. The reference characteristic generation unit 114 registers the reference SOC-OCV curve, the reference RC, and the reference SOH generated for each battery group in the group characteristic maintaining unit 123.

The cell type identification unit 113 identifies the type of cells included in an undefined battery pack 41 based on a degree of agreement between the SOC-OCV curve of the cell block of the undefined battery pack 41 and the SOC-OCV curve of an already-defined cell block and based on a degree of agreement between the RC of the cell block of the undefined battery pack 41 and the RC of the already-defined cell block. When the degree of agreement between the SOC-OCV curves exceeds the first preset value and the degree of agreement between the RC's exceeds the second preset value, the cell type identification unit 113 determines that the cell type of the undefined battery pack 41 and the cell type of the already-defined cell block match. If one of the degrees of agreement fails to meet the first preset value or the second preset value, the cell type identification unit 113 determines that the cell type of the cell block of the undefined battery pack 41 and the cell type of the already-defined cell block do not match. The cell type identification unit 113 compares, for each class described above, the RC of the cell block of the undefined battery pack 41 and a referenced already-defined resistance capacity product.

The cell type identification unit 113 can refer to the reference SOC-OCV curve and the reference RC as the SOC-OCV curve and the RC of the already-defined cell block. That is, the cell type identification unit 113 can identify the type of cells type included in the undefined battery pack 41 and the battery group based on the degree of agreement between the SOC-OCV curve of the cell block of the undefined battery pack 41 and the reference SOC-OCV curve and based on the degree of agreement between the RC of the cell block of the undefined battery pack 41 and the reference RC. It should be noted that the cell type identification unit 113 can also refer to the estimated SOC-OCV curve and the estimated RC of any already-defined cell block registered in the battery-specific characteristic maintaining unit 122.

The cell type identification unit 113 scales the SOC axis of the SOC-OCV curve of the cell block included in the undefined battery pack 41 or the SOC axis of the referenced already-defined SOC-OCV curve to result in the highest degree of agreement between the SOC-OCV curve of the cell block of the undefined battery pack 41 and the referenced already-defined SOC-OCV curve. The specific scaling method will be described later. When comparing the RC of the cell block of the undefined battery pack 41 with the referenced already-defined RC, the cell type identification unit 113 uses a coefficient, which is used to scale the SOC axis, to correct the RC of the cell block of the undefined battery pack 41 or the referenced already-defined RC. The specific correction method will be described later.

The characteristic prediction unit 115 can estimate a future capacity (more specifically, FCC) of the undefined battery pack 41 based on the initial SOH of the cell block included in the undefined battery pack 41 and the referenced already-defined SOH. The characteristic prediction unit 115 can also estimate a future SOC-OCV curve of the undefined battery pack 41 based on the initial SOC-OCV curve of the cell block included in the undefined battery pack 41 and the referenced already-defined SOC-OCV curve. The characteristic prediction unit 115 can also estimate a future resistance of the undefined battery pack 41 based on the initial resistance of the cell block included in the undefined battery pack 41 and the referenced already-defined resistance. The characteristic prediction unit 115 can also estimate a future resistance of the undefined battery pack 41 temperature by temperature.

The result notification unit 116 notifies the information terminal of the prospective purchaser or the purchasing representative of a determination result including a predicted transition of the capacity and a predicted transition of the resistance of the cell block included in the target battery pack 41. The characteristic prediction unit 115 may generate a predicted transition of at least one of the cruising distance and temperature-specific electricity cost of the electric-powered vehicle 3 based on the predicted transition of the capacity and the predicted transition of the resistance. The result notification unit 116 may notify the information terminal of the prospective purchaser or the purchasing representative of a predicted transition of at least one of the cruising distance or the temperature-specific electricity cost of the electric-powered vehicle 3.

FIG. 4 is a flowchart showing a schematic operation of the battery analysis system 1 according to the embodiment. The process shown in FIG. 4 may be executed when, for example, a battery log of a new battery cell or a new battery pack 41 is collected or at one-month cycle. The data acquisition unit 111 reads the battery log from the battery log maintaining unit 121 for each battery ID (S10). The battery-specific characteristic generation unit 112 updates the battery characteristics for each battery ID based on the battery log thus read and registers the updated battery characteristics for each battery ID in the battery-specific characteristic maintaining unit 122 (S11).

The cell type identification unit 113 executes a process of determining a degree of agreement between the SOC-OCV curve of the cell block of the undefined battery pack 41 and the SOC-OCV curve of the already-defined cell block (S20). When the cell type identification unit 113 finds a match (Y in S21), the cell type identification unit 113 executes a process of determining a degree of agreement between the RC of the undefined battery pack 41 and the RC of the already-defined cell block (S22). When the cell type identification unit 113 finds a match, the cell type identification unit 113 determines that the cells included in the cell block of the undefined battery pack 41 and those included in the already-fined cell block are of the same type.

When the cell type identification unit 113 finds a mismatch between the SOC-OCV curve of the cell block of the undefined battery pack 41 and the SOC-OCV curve of the already-defined cell block (N in S21), the cell type identification unit 113 skips the process of determining a degree of agreement in RC in step S22. The above steps S10, S11, S20, S21, and S22 are executed for all battery IDs (S23).

When the battery characteristics updating process (S10, S11) and the cell type identification process (S20, S21, S22) are completed for all battery ID's (Y in S23), the reference characteristic generation unit 114 updates the reference battery characteristics for each battery group including cells of the same type and registers the updated battery characteristics for each battery group in the group characteristic maintaining unit 123 (S30). Step S30 is executed for all battery groups (S31).

When the process to update the reference battery characteristics (S30) is completed for all battery groups (Y in S31), the characteristic prediction unit 115 predicts future battery characteristics for each battery ID (S40). Step S40 is executed for all battery IDs (S41). When the process to predict the battery characteristics (S40) is completed for all battery ID's (Y in S41), the entire process is completed. Hereinafter, each step will be described in detail.

FIGS. 5A-5B are diagrams for illustrating a battery log collection step. FIG. 5A shows a schematic diagram of a single cell, and FIG. 5B shows a schematic diagram of the battery pack 41. Charge/discharge data for the single cell or the battery pack 41 is registered in the battery log maintaining unit 121 as a battery log. The charge/discharge data may be acquired by a charge/discharge test using an actual battery or may be acquired from the data server 2 without an actual battery. A battery ID (for example, a serial number) is assigned to the battery log for each battery cell or battery pack 41.

Hereinafter, the units of the parameters are as follows.
t: Timestamp 1 [sec] period
Ib: Block current [A] (+indicates charge)
Vb: Block voltage [V]
Tb: Block temperature [° C.]

FIG. 5B shows an example in which one temperature sensor (thermistor) is provided in each of n cell blocks connected in series. When the number of temperature sensors is smaller than the number of cell blocks, the block temperature of the cell block without a temperature sensor will be an estimated value.

The battery-specific characteristic generation unit 112 calculates the estimated SOCe [%] of the cell block at each time stamp from the battery log read for each battery ID. A general current integration method can be used as a calculation method. The battery-specific characteristic generation unit 112 registers the estimated SOCe of the cell block thus calculated at each time stamp in the battery log maintaining unit 121. The SOC of the cell block estimated by the battery control unit 46 of the battery pack 41 may be used directly.

FIG. 6 is a diagram showing a calculated example of the estimated SOC-OCV curve (estimated OCVe curve). The battery-specific characteristic generation unit 112 maps the estimated SOCe and the block voltage Vb (OCV) during a long pause (for example, a pause for 15 minutes or longer). A representative value (for example, median, average value) of the estimated SOCe of a plurality of cell blocks included in the battery pack 41 may be used as the estimated SOCe of the cell block plotted. Similarly, a representative value (for example, median, average value) of the block voltage Vb of a plurality of cell blocks included in the battery pack 41 may be used as the block voltage Vb plotted.

FIG. 6 shows an example in which a new EV is caused to run and stop repeatedly to acquire a discrete SOC-OCV curve of “medium”−“high” SOC. In FIG. 6, the SOC-OCV curve acquired in a short period of time (one day, etc.) is assumed, but it is desirable to result in a map of successively higher accuracy and more extensive range by, for example, repeatedly causing the vehicle to run/stop for a long period of time and calculating representative values (for example, medians, simple average values, weighted average values) of previous and current values. When the vehicle is caused to continue to run for a long time, it is possible to acquire OCV of low SOC. The battery-specific characteristic generation unit 112 registers the calculated estimated SOC-OCV curve (hereinafter referred to as estimated OCVe curve as appropriate) in the battery-specific characteristic maintaining unit 122 for each battery ID.

The battery-specific characteristic generation unit 112 calculates an estimated resistance Re [mQ] of the cell block from the battery log read for each battery ID. First, the battery-specific characteristic generation unit 112 determines a block resistance Rb of each cell block by determining an ohmic resistance as given by (expression 1) below.

$$Rbi ( t ) = ( Δ Vbi ( t ) / Δ Ib ( t ) ) * 1000 ) \qquad ( expression 1 )$$

where i is a parameter indicating the number of cell blocks in series, and 1000 is a constant for unit conversion.

It is noted that a resistance component other than ohmic resistance (for example, a resistance component such as diffusion resistance having a value inversely proportional to the number of cells in parallel) may be used.

The battery-specific characteristic generation unit 112 determines the estimated resistance Re by calculating a representative value for each block resistance Rb of the cell block, for each time stamp, for each condition (e.g., degree of degradation, remaining capacity, temperature), etc.

FIG. 7 is a diagram showing examples of the estimated resistance Re calculated under each condition. For example, the conditions are defined as follows.

Degree of degradation: Number of cycles

Remaining capacity: Estimated SOCe

Temperature: Block temperature Tb

Hereinafter, for the purpose of simplicity, a description will be given of a case in which each condition is classified into three stages: “low”, “medium”, and “high”. FIG. 7 shows an example in which a new EV is caused to run and stop repeatedly to acquire only the estimated resistance Re at “low” degree of degradation, “medium”−“high” remaining capacity, and “medium”−“high” temperature. Referring to FIG. 7, the estimated resistance Re acquired in a short period of time (one day, etc.) is assumed, but it is desirable to result in a map of successively higher accuracy and increased number of conditions by, for example, repeatedly causing the vehicle to run/stop for a long period of time and calculating representative values (for example, medians, simple average values, weighted average values) of previous and current values. The battery-specific characteristic generation unit 112 registers, for each battery ID, the calculated estimated resistance Re for each condition in the battery-specific characteristic maintaining unit 122.

The battery-specific characteristic generation unit 112 calculates an estimated FCCe [Ah] from the battery log read for each battery ID. First, the battery-specific characteristic generation unit 112 determines the estimated FCCe at each time stamp from an integrated value of the block current Ib during a period of transition from a given OCV to another OCV and from a differential SOCv estimated from the estimated OCVe curve as given by (expression 2) below to find a current capacity [Ah].

$${FCC}_{e} ( t ) = ( Δ Ib ( t ) / ( Δ {SOC}_{V} ( t ) ) / 36 ) \qquad ( expression 2 )$$

where 36 is a constant for unit conversion (conversion from second to hour and conversion from percent to decimal).

It is noted that a capacity component other than current capacity [Ah] (for example, a capacity component such as power capacity [Wh] of each cell block having a value proportional to the number of cells in parallel) may be used.

The battery-specific characteristic generation unit 112 determines the final estimated FCCe by calculating a representative value at estimated SOH=100%, which is described later, and at each time stamp. In this embodiment, the estimated FCCe is defined as the initial FCC acquired in a short period of time (one day, etc.). In this case, the current capacity [Ah] at a given degree of degradation is considered to be constant regardless of a condition such as temperature. The battery-specific characteristic generation unit 112 registers the estimated FCCe thus calculated in the battery-specific characteristic maintaining unit 122 for each battery ID.

The battery-specific characteristic generation unit 112 calculates the estimated SOHe [%] for each battery ID. The estimated SOHe is defined as the capacity maintenance rate relative to the rating capacity at each degree of degradation.

FIG. 8 is a diagram showing examples of the estimated SOHe calculated at each degree of degradation. As described above, the degree of degradation is defined by the number of cycles in this embodiment. The battery-specific characteristic generation unit 112 registers, for each battery ID, the calculated estimated SOHe at each degree of degradation in the battery-specific characteristic maintaining unit 122.

The cell type identification unit 113 determines whether the estimated OCVe curve of a battery ID for which the battery group (e.g., unique name) is undefined matches another estimated OCVe curves for which the battery group is undefined or a known reference OCVr curve. When the OCV curves match, it is likely that the cells are of the same cell type. When the definition of SOC in the OCV curves compared differs, however, a match is not found even if the OCV curves are the same so that the cell type identification unit 113 scales the SOC axis.

FIGS. 9A-9B are diagrams showing the reference OCVr curve and a calculated example of the estimated OCVe curve superimposed on graphs. FIG. 9A shows a graph before the SOC axis of the estimated OCVe curve is scaled, and FIG. 9B shows a graph after the SOC axis of the estimated OCVe curve is scaled. In the example shown in FIG. 9A, SOC of the estimated OCVe curve is defined between OCV3.0-4.2 V, and SOC of the reference OCVr curve is defined between OCV3.0-4.0 V. Even in the case the same cell type is packed, the definition of SOC may differ depending on a difference in safety design or criterion for degradation between battery manufacturers.

In the example shown in FIG. 9A, the estimated OCVe curve has a wider operating voltage range, showing that the cell block of an undefined battery ID has a larger FCC than the cell block having the characteristics of the reference OCVr curve. The cell type identification unit 113 clips a part of the reference OCVr curve in the range the minimum OCV-the maximum OCV of the estimated OCVe curve and checks the clipped reference OCVr curve against the estimated OCVe curve.

When checking the curves against each other, the cell type identification unit 113 scales the SOC axis of the estimated OCVe curve with a scaling coefficient (hereinafter referred to here as the first SOC coefficient). For example, the cell type identification unit 113 changes the first SOC coefficient in the range 0.5-1.5 to scale the SOC axis of the estimated OCVe curve successively and derives the first SOC coefficient that results in the highest degree of agreement with the reference OCVr curve.

Specifically, the cell type identification unit 113 derives the first SOC coefficient that minimizes a sum of absolute differences between the scaled estimated OCVe curve and the reference OCVr curve. When the sum of absolute differences is equal to or smaller than the first threshold value, the cell type identification unit 113 assumes that the OCV curves match and registers the first SOC coefficient at that time (1.1 in the example shown in FIG. 9B) in the battery-specific characteristic maintaining unit 122. The first SOC coefficient=1.1 indicates that the FCC of the cell block having the characteristics of the estimated OCVe curve is 1.1 times the FCC of the cell block having the characteristics of the reference OCVr curve.

When the estimated OCVe curve of the battery ID for which the battery group is defined does not match the reference OCVr curve of the same battery group, the cell type identification unit 113 returns the battery group of that battery ID to an undefined state.

The battery-specific characteristic generation unit 112 calculates an estimated RCe [mΩ. Ah] based on the estimated resistance Re [mΩ] of the cell block and the estimated FCCe [Ah] thus calculated. The estimated RC is defined as a product of the estimated resistance Re and the estimated FCCe at “low” degree of degradation.

FIG. 10 is a diagram showing calculated examples of the estimated resistance Re, the estimated RCe, and the estimated RCe after adjustment at “low” degree of degradation. When the estimated FCCe is 72.0 [Ah], for example, the estimated resistance Re at “low” degree of degradation shown in the table in the middle is derived from the estimated RCe at “low” degree of degradation shown in the upper table.

The cell type identification unit 113 determines whether the estimated RCe of the battery ID being processed matches another estimated RCe for which the battery group is undefined or a known reference RCr. The battery ID for which the estimated OCVe curve matches another estimated OCVe for which the battery group is undefined or the known reference OCVr curve will be the battery ID being processed. When the RCs match, it is likely that the cells are of the same cell type. As given by (expression 3)-(expression 5) below, RC is an index in which an element of the number of cells in parallel is removed and is an index useful to identify a cell type for which the number of cells in parallel is unknown.

$$Block resistance = cell resistance / number of cells in parallel \qquad ( expression 3 )$$

$$Block capacity = cell capacity * number of cells in parallel \qquad ( expression 4 )$$

$$RC = block resistance * block capacity = cell resistance * cell capacity \qquad ( expression 5 )$$

When the definition of SOC as determined by the RCs to be compared differs, however, a match is not found even if the RC's are the same. Since the estimated RCe is the first SOC coefficient times the reference RCr, the cell type identification unit 113 scales the estimated RCe by dividing the estimated RCe by the first SOC coefficient (1.1 in the above example). The lower table shows the estimated RCe after scaling.

When a sum of absolute differences between the estimated RCe and the reference RCr under each condition is equal to or smaller than the second threshold value at “low” degree of degradation, for example, the cell type identification unit 113 assumes that the RC's match and updates the undefined battery group to the battery group of the known reference RCr.

FIG. 11 is a diagram showing calculated examples of the estimated RCe and the reference RCr after adjustment at “low” degree of degradation. The cell type identification unit 113 compares the RCe after adjustment and the reference RCr at “low” degree of degradation under the same condition. In the example shown in FIG. 11, the cell type identification unit 113 calculates absolute differences between the estimated RCe and the reference RCr under two conditions, i.e., the condition of “medium” temperature/“medium” remaining capacity and the condition of “medium” temperature/“high” remaining capacity and compares the sum of the differences with the second threshold value. At degrees of degradation other than “low”, individual differences in RC are considered to be large so that a comparison is not performed.

When the estimated RCe of the battery ID for which the battery group is defined does not match the reference RCr of the same battery group, the cell type identification unit 113 returns the battery group of that battery ID to an undefined state. Thus, the cell type identification unit 113 considers cells of the battery ID for which a match is found in both the OCV curve and RC to be of the same cell type. The cell type identification unit 113 excludes a battery ID that does not meet either one or both from the battery group.

The reference characteristic generation unit 114 updates the reference SOHr for each degree of degradation by a method such as calculating representative values (for example, medians, simple average values, weighted average values) of all estimated SOHe's of the same battery group as that of the reference SOHr. The reference characteristic generation unit 114 registers the updated reference SOHr for each degree of degradation in the group characteristic maintaining unit 123.

FIG. 12 is a diagram showing an example of updating the reference SOHr. In the example shown in FIG. 12, the reference characteristic generation unit 114 updates the reference SOHr by calculating a weighted average of the known reference SOHr and three estimated SOHe's, respectively, at “low” and “medium” degrees of degradation. At “high” degree of degradation, the reference characteristic generation unit 114 replaces the missing known reference SOHr with the estimated SOHe in the upper left.

For all estimated OCVe curves of the same battery group, the reference characteristic generation unit 114 updates the reference OCVr curve by synthesizing the estimated OCVe curve with the reference OCVr curve for each battery ID such that the range of OCV is most extensive.

FIGS. 13A-13B are diagrams showing the reference OCVr curve and a calculated example of the estimated OCVe curve superimposed on graphs. The reference OCVr curve shown in FIG. 13A is one before an update, and the reference OCVr curve shown in FIG. 13B is one after an update. In the example shown in FIGS. 13A-13B, the maximum OCV in the reference OCVr curve is 4.0 V, and the maximum OCV in the estimated OCVe curve is 4.2 V. The reference characteristic generation unit 114 clips a part of the reference OCVr curve in the range the minimum OCV-the maximum OCV of the estimated OCVe curve and checks the clipped reference OCVr curve against the estimated OCVe curve.

When checking the curves, the reference characteristic generation unit 114 scales the SOC axis of the reference OCVr curve with a scaling coefficient (hereinafter referred to as the second SOC coefficient). For example, the reference characteristic generation unit 114 changes the second SOC coefficient in the range 0.5-1.5 to scale the SOC axis of the reference OCVr curve successively and derives the second SOC coefficient that results in the highest degree of agreement with the estimated OCVe curve.

Specifically, the reference characteristic generation unit 114 derives the second SOC coefficient that minimizes a sum of absolute differences between the scaled reference OCVr curve and the estimated OCVe curve. When the sum of absolute differences is equal to or smaller than the first threshold value, the reference characteristic generation unit 114 assumes that the OCV curves match and temporarily maintains the second SOC coefficient at that time (0.9 in the example shown in FIG. 13B). The second SOC coefficient=0.9 indicates that the FCC of the cell block having the characteristics of the reference OCVr curve is 0.9 times the FCC of the cell block having the characteristics of the estimated OCVe curve.

When the second SOC coefficient is smaller than 1, the reference characteristic generation unit 114 finds the scaled reference OCVr curve by extrapolation using the estimated OCVe curve. When the second SOC coefficient is equal to or larger than 1, extrapolation does not take place. The reference characteristic generation unit 114 updates a zone of the scaled reference OCVr curve that overlaps the estimated OCVe curve by a method such as calculating representative values (for example, medians, simple average values, weighted average values) of the scaled reference OCVr curve and the estimated OCVe curve. The reference characteristic generation unit 114 registers the reference OCVr curve after the update in the group characteristic maintaining unit 123.

Since the reference RCr is the second SOC coefficient times the estimated RCe, the reference characteristic generation unit 114 adjusts the reference RCr by dividing the reference RCr by the second SOC coefficient (0.9 in the above example).

FIG. 14 is a diagram showing calculated examples of the estimated RCe before adjustment and the estimated RCe after adjustment. The reference characteristic generation unit 114 adjusts the estimated RCe under each condition by dividing the estimated RCe under each condition by the second SOC coefficient (0.9).

The reference characteristic generation unit 114 updates the reference RCr by a method such as calculating representative values (for example, medians, simple average values, weighted average values) of the reference RCr and the estimated RCe.

FIG. 15 is a diagram showing calculated examples of the estimated RCe and the reference RCr after the update. It is assumed that the estimated RCe shown in the upper graph of FIG. 15 has been calculated through “high” degree of degradation. The reference characteristic generation unit 114 updates the reference RCr by calculating a weighted average of the reference RCr shown in the lower graph FIG. 14 and the estimated RCe shown in the upper graph of FIG. 15 for each condition. The reference characteristic generation unit 114 replaces the missing known reference RCr with the estimated RCe shown in the upper graph of FIG. 15 under the condition of “low” degree of degradation/“high” temperature/“medium” remaining capacity. The reference characteristic generation unit 114 registers the reference RCr after the update in the group characteristic maintaining unit 123.

When the second SOC coefficient>1.0 (in the absence of extrapolation of the reference OCVr curve), the reference RCr after the update is lower than it actually is due to the second SOC coefficient, so the reference RCr after the update is multiplied by the second SOC coefficient to restore the scale. When the second SOC coefficient>1.0, the cell block having the characteristics of the reference OCVr curve has a larger FCC than the cell block having the characteristics of the estimated OCVe curve. For compatibility with the FCC of the cell block having the characteristics of the estimated OCVe curve, the reference RCr is reduced temporarily, and the reduction is reversed after the update. When the second SOC coefficient>1.0, the reference OCVr curve is extrapolated so that there is no need to restore the reference RCr after expanding it. In this way, learning is caused to progresses in a direction in which the SOC axis of the reference OCVr curve constantly expands. As learning progresses, the number of cases in which the second SOC coefficient>1.0 decreases.

The characteristic prediction unit 115 updates the estimated SOHe for each battery ID by a method such as calculating a representative value (for example, median, simple average value, weighted average value) of the reference SOHr of the same battery group as that of the estimated SOHe for each battery ID.

FIG. 16 is a diagram showing an example of updating the estimated SOHe. Referring to the example of the second row in FIG. 16, the characteristic prediction unit 115 updates the estimated SOHe at “medium” degree of degradation to the average value of the estimated SOHe before the update and the reference SOHr. In the example of the third row, the characteristic prediction unit 115 replaces the missing estimated SOHe at “high” degree of degradation with the reference SOHr at “high” degree of degradation. In the example of the fourth row, the characteristic prediction unit 115 replaces the missing estimated SOHe at “medium”, “high” degrees of degradation with the reference SOHr at “medium”, “high” degrees of degradation, respectively. The characteristic prediction unit 115 registers the estimated SOHe after the update in the battery-specific characteristic maintaining unit 122.

For each battery ID, the characteristic prediction unit 115 can predict the estimated FCCe up to “high” degree of degradation at the stage of “low” degree of degradation, by referring to the estimated SOHe and the estimated FCCe after the update.

FIG. 17 is a diagram showing an example of predicting the estimated FCCe. The left diagram of FIG. 17 shows the estimated SOHe after the update in the second row of FIG. 16. When the estimated FCCe of the cell block at “low” degree of degradation is 72.0 [Ah], it can be predicted that the estimated FCCe at “medium” degree of degradation is 61.2 [Ah], and the estimated FCCe at “high” degree of degradation is 50.4 [Ah]. The characteristic prediction unit 115 registers the predicted estimated FCCe in the battery-specific characteristic maintaining unit 122. In this way, it is possible to predict the battery capacity after degradation in a short period (one day, etc.) of operation, and the value provided until the end of life of the target battery-equipped product (for example, the cruising distance of an EV) can be grasped.

The characteristic prediction unit 115 extrapolates the estimated OCVe curve by using the reference OCVr curve that results from scaling the SOC axis of the reference OCVr curve of the same battery group with the first SOC coefficient. The characteristic prediction unit 115 updates a zone of the estimated OCVe curve that overlaps the scaled reference OCVr curve by a method such as calculating representative values (for example, medians, simple average values, weighted average values) of the estimated OCVe curve and the scaled reference OCVr curve. The characteristic prediction unit 115 derives the first SOC coefficient by checking the estimated OCVe curve after the update against the reference OCVr curve.

FIG. 18 is a diagram showing calculated examples of the estimated OCVe curve before the update and the estimated OCVe curve after the update superimposed on a graph. In the example shown in FIG. 18, scaling is not required because the definition of SOC in the estimated OCVe curve and that of the reference OCVr curve match (the first SOC coefficient=the second SOC coefficient=1.0). The characteristic prediction unit 115 registers the estimated OCVe curve after the update and the newly derived first SOC coefficient in the battery-specific characteristic maintaining unit 122. In this way, a highly accurate estimated OCVe curve can be obtained in a short period (one day, etc.) of operation.

The characteristic prediction unit 115 can calculate a reference resistance Rr from the reference RCr and predict the estimated resistance Re. Since the reference RCr is the second SOC coefficient times the estimated RCe, the characteristic prediction unit 115 adjusts the reference RCr by dividing the reference RCr by the second SOC coefficient. In the example of FIG. 18, no adjustment is required. The characteristic prediction unit 115 calculates the reference resistance Rr by dividing the adjusted reference RCr by the estimated FCCe shown in FIG. 17 for each degree of degradation.

FIG. 19 is a diagram showing calculated examples of the reference RCr and the reference resistance Rr. The characteristic prediction unit 115 calculates the reference resistance Rr under each condition by dividing the reference RCr under each condition by the estimated FCCe at each degree of degradation.

The characteristic prediction unit 115 updates the estimated resistance Re for each battery ID by a method such as calculating a representative value (for example, median value, simple average value, weighted average value) of the reference resistance Rr of the same battery group as that of the estimated resistance Re for each battery ID.

FIG. 20 is a diagram showing an example of updating the estimated resistor Re. The characteristic prediction unit 115 updates the estimated resistance Re under a condition in which a value is found to the average value of the estimated resistance Re and the reference resistance Rr, respectively. The characteristic prediction unit 115 replaces the estimated resistance Re under a condition in which a value is missing with the reference resistor Rr, respectively.

Thus, it is possible to predict the estimated resistance Re under various conditions once the estimated resistance Re is acquired under certain conditions. By predicting battery resistance after degradation or at low temperature based on operation data for a short-term (one day, etc.), it is possible to grasp the value (e.g., the electricity cost of an EV) of the target battery-equipped product under various conditions.

As described above, according to this embodiment, it is possible to identify the type of cells included in the cell block of an unknown battery pack 41 without disassembling the battery pack 41, by comparing the estimated OCVe curve and estimated RCe based on the initial log of the cell block of the unknown battery pack 41 with the reference OCVr curve and the reference RCr. Given the cell resistance and the cell capacity, it will be principally possible to identify a cell type, but it is difficult to estimate a cell type in the unknown battery pack 41 by referring to the cell resistance and the cell capacity because the number of cells in parallel is unknown. In this regard, this embodiment makes it possible to identify a cell type even if the number of cells in parallel is unknown, by using RC as an index.

The shape of the OCV curve may vary according to the definition of SOC (operating voltage range, etc.) even in the case of the same cell type, but the embodiment is equipped with a correction mechanism and so makes it possible to determine a match between OCV curves with high accuracy.

The prospective purchaser or the purchasing representative of the electric-powered vehicle 3 can check in advance whether the catalog specification and the actual performance are consistent based on the battery performance predicted by the battery analysis system 1. It is also possible to check in advance whether there is a defect that is not described in the catalog specification.

Given above is a description of the present disclosure based on the embodiment. The embodiment is intended to be illustrative only and it will be understood by those skilled in the art that various modifications to combinations of constituting elements and processes are possible and that such modifications are also within the scope of the present disclosure.

In the above embodiment, a four-wheeled electric-powered vehicle is assumed as the electric-powered vehicle 3. The electric-powered vehicle 3 may be an electric motorcycle (electric scooter) or an electric bicycle. Further, electric-powered vehicles include not only full-spec electric-powered vehicles but also low-speed electric-powered vehicles such as golf carts and land cars used in shopping malls, entertainment facilities, etc. The battery analysis system 1 according to the present disclosure can also be applied to battery analysis of battery packs 41 mounted on electric ships, multicopters (drones), stationary electricity storage systems, information equipment (e.g., notebook PCs, tablets, smartphones) and the like.

The embodiment may be defined by the following items.

### [Item 1]

A battery analysis system (1) including:
a data acquisition unit (111) that acquires battery data including i) a voltage of at least one cell block included in a battery pack (41) including cell blocks connected in series, the cell block being comprised of one or more cells (E1-En) connected in parallel and ii) a current flowing in a plurality of cell blocks connected in series;
a battery-specific characteristic generation unit (112) that estimates, for each battery pack (41), an SOC (State of Charge)-OCV (Open Circuit Voltage) curve of a cell block included in the battery pack (41), a resistance of the cell block, and a capacity of the cell block, and calculates a resistance capacity product derived from multiplying the resistance of the cell block by the capacity of the cell block; and
a cell type identification unit (113) that identifies a type of the cell (E1-En) included in an undefined battery pack (41) based on a degree of agreement between the SOC-OCV curve of the cell block of the undefined battery pack (41) and the SOC-OCV curve of an already-defined cell block and based on a degree of agreement between the resistance capacity product of the cell block of the undefined battery pack (41) and the resistance capacity product of the already-defined cell block.

According to this embodiment, it is possible to identify the type of the cell (E1-En) included in the cell block (41) of the undefined battery pack (41) without disassembling the battery pack (41).

### [Item 2]

The battery analysis system (1) according to Item 1, further including:
a reference characteristic generation unit (114) that generates a reference SOC-OCV curve and a reference resistance capacity product for each battery group based on a plurality of SOC-OCV curves and a plurality of resistance capacity products of a plurality of cell blocks including cells (E1-En) of the same type,
wherein the cell type identification unit (113) identifies i) a type of the cell (E1-En) included in the undefined battery pack (41) and ii) a battery group, based on a degree of agreement between the SOC-OCV curve of the cell block of the undefined battery pack (41) and the reference SOC-OCV curve and based on a degree of agreement between the resistance capacity product of the cell block of the undefined battery pack (41) and the reference resistance capacity product.

According to this embodiment, it is possible to identify a battery group that the cell block (41) of the undefined battery pack (41) should belong with high accuracy.

### [Item 3]

The battery analysis system (1) according to Item 2, wherein the cell type identification unit (113) scales an SOC axis of an SOC-OCV curve of the cell block included in the undefined battery pack (41) or an SOC axis of a referenced already-defined SOC-OCV curve to result in the highest degree of agreement between the SOC-OCV curve of the cell block of the undefined battery pack (41) and the referenced already-defined SOC-OCV curve.

According to this embodiment, it is possible to determine a match between SOC-OCV curves with high accuracy.

### [Item 4]

The battery analysis system (1) according to Item 3, wherein the cell type identification unit (113) uses a coefficient derived from scaling the SOC axis to correct the resistance capacity product of the cell block of the undefined battery pack (41) or the referenced already-defined resistance capacity product.

According to this embodiment, it is possible to determine a match between resistance capacity products with high accuracy.

### [Item 5]

The battery analysis system (1) according to Item 2,
wherein the data acquisition unit (111) further acquires a temperature of at least one cell included in the battery pack (41),
wherein the battery-specific characteristic generation unit (112) generates the resistance capacity product of the cell block for each of a plurality of classes derived from division with reference to at least one of degree of degradation, temperature, or remaining capacity,
wherein the reference characteristic generation unit (114) generates the reference resistance capacity product for each of the plurality of classes, and
wherein the cell type identification unit (113) compares, for each class, the resistance capacity product of the cell block of the undefined battery pack (41) with the referenced already-defined reference resistance capacity product.

According to this embodiment, it is possible to determine a match between resistance capacity products with high accuracy by comparing resistance capacity products under various conditions.

### [Item 6]

The battery analysis system (1) according to Item 2,
wherein the battery-specific characteristic generation unit (112) estimates, for each battery pack (41), an SOH (State Of Health) of the cell block included in the battery pack (41),
wherein the reference characteristic generation unit (114) generates a reference SOH for each battery group based on a plurality of SOH's of a plurality of cell blocks including cells (E1-En) of the same type,
wherein the battery analysis system (1) further includes:
a characteristic prediction unit (115) that predicts at least one of a future capacity or a future resistance of the undefined battery pack (41) based on an initial SOH of the cell block included in the undefined battery pack (41) and a referenced already-defined SOH.

According to this embodiment, it is possible to predict a transition of future capacity degradation at an early stage of the operation of the battery pack (41).

### [Item 7]

A battery analysis method including:
acquiring battery data including i) a voltage of at least one cell block included in a battery pack (41) including cell blocks connected in series, the cell block being comprised of one or more cells (E1-En) connected in parallel and ii) a current flowing in a plurality of cell blocks connected in series;
estimating, for each battery pack (41), an SOC (State of Charge)-OCV (Open Circuit Voltage) curve of a cell block included in the battery pack (41), a resistance of the cell block, and a capacity of the cell block, and calculating a resistance capacity product derived from multiplying the resistance of the cell block by the capacity of the cell block; and
identifying a type of the cell (E1-En) included in an undefined battery pack (41) based on a degree of agreement between the SOC-OCV curve of the cell block of the undefined battery pack (41) and the SOC-OCV curve of an already-defined cell block and based on a degree of agreement between the resistance capacity product of the cell block of the undefined battery pack (41) and the resistance capacity product of the already-defined cell block.

According to this embodiment, it is possible to identify the type of the cell (E1-En) included in the cell block (41) of the undefined battery pack (41) without disassembling the battery pack (41).

### [Item 8]

A battery analysis program including computer-implemented modules including:
a module that acquires battery data including i) a voltage of at least one cell block included in a battery pack (41) including cell blocks connected in series, the cell block being comprised of one or more cells (E1-En) connected in parallel and ii) a current flowing in a plurality of cell blocks connected in series;
a module that estimates, for each battery pack (41), an SOC (State of Charge)-OCV (Open Circuit Voltage) curve of a cell block included in the battery pack (41), a resistance of the cell block, and a capacity of the cell block, and calculates a resistance capacity product derived from multiplying the resistance of the cell block by the capacity of the cell block; and
a module that identifies a type of the cell (E1-En) included in an undefined battery pack (41) based on a degree of agreement between the SOC-OCV curve of the cell block of the undefined battery pack (41) and the SOC-OCV curve of an already-defined cell block and based on a degree of agreement between the resistance capacity product of the cell block of the undefined battery pack (41) and the resistance capacity product of the already-defined cell block.

According to this embodiment, it is possible to identify the type of the cell (E1-En) included in the cell block (41) of the undefined battery pack (41) without disassembling the battery pack (41).

1. A battery analysis system comprising:
a data acquisition unit that acquires battery data including i) a voltage of at least one cell block included in a battery pack including cell blocks connected in series, the cell block being comprised of one or more cells connected in parallel and ii) a current flowing in a plurality of cell blocks connected in series;
a battery-specific characteristic generation unit that estimates, for each battery pack, an SOC (State of Charge)-OCV (Open Circuit Voltage) curve of a cell block included in the battery pack, a resistance of the cell block, and a capacity of the cell block, and calculates a resistance capacity product derived from multiplying the resistance of the cell block by the capacity of the cell block; and
a cell type identification unit that identifies a type of the cell included in an undefined battery pack based on a degree of agreement between the SOC-OCV curve of the cell block of the undefined battery pack and the SOC-OCV curve of an already-defined cell block and based on a degree of agreement between the resistance capacity product of the cell block of the undefined battery pack and the resistance capacity product of the already-defined cell block.

2. The battery analysis system according to claim 1, further comprising:
a reference characteristic generation unit that generates a reference SOC-OCV curve and a reference resistance capacity product for each battery group based on a plurality of SOC-OCV curves and a plurality of resistance capacity products of a plurality of cell blocks including cells of the same type,
wherein the cell type identification unit identifies i) a type of the cell included in the undefined battery pack and ii) a battery group, based on a degree of agreement between the SOC-OCV curve of the cell block of the undefined battery pack and the reference SOC-OCV curve and based on a degree of agreement between the resistance capacity product of the cell block of the undefined battery pack and the reference resistance capacity product.

3. The battery analysis system according to claim 2,
wherein the cell type identification unit scales an SOC axis of an SOC-OCV curve of the cell block included in the undefined battery pack or an SOC axis of a referenced already-defined SOC-OCV curve to result in the highest degree of agreement between the SOC-OCV curve of the cell block of the undefined battery pack and the referenced already-defined SOC-OCV curve.

4. The battery analysis system according to claim 3,
wherein the cell type identification unit uses a coefficient derived from scaling the SOC axis to correct the resistance capacity product of the cell block of the undefined battery pack or the referenced already-defined resistance capacity product.

5. The battery analysis system according to claim 2,
wherein the data acquisition unit further acquires a temperature of at least one cell included in the battery pack,
wherein the battery-specific characteristic generation unit generates the resistance capacity product of the cell block for each of a plurality of classes derived from division with reference to at least one of degree of degradation, temperature, or remaining capacity,
wherein the reference characteristic generation unit generates the reference resistance capacity product for each of the plurality of classes, and
wherein the cell type identification unit compares, for each class, the resistance capacity product of the cell block of the undefined battery pack with the referenced already-defined reference resistance capacity product.

6. The battery analysis system according to claim 2,
wherein the battery-specific characteristic generation unit estimates, for each battery pack, an SOH (State Of Health) of the cell block included in the battery pack,
wherein the reference characteristic generation unit generates a reference SOH for each battery group based on a plurality of SOH's of a plurality of cell blocks including cells of the same type,
wherein the battery analysis system further comprises:
a characteristic prediction unit that predicts at least one of a future capacity or a future resistance of the undefined battery pack based on an initial SOH of the cell block included in the undefined battery pack and a referenced already-defined SOH.

7. A battery analysis method comprising:
acquiring battery data including i) a voltage of at least one cell block included in a battery pack including cell blocks connected in series, the cell block being comprised of one or more cells connected in parallel and ii) a current flowing in a plurality of cell blocks connected in series;
estimating, for each battery pack, an SOC (State of Charge)-OCV (Open Circuit Voltage) curve of a cell block included in the battery pack, a resistance of the cell block, and a capacity of the cell block, and calculating a resistance capacity product derived from multiplying the resistance of the cell block by the capacity of the cell block; and
identifying a type of the cell included in an undefined battery pack based on a degree of agreement between the SOC-OCV curve of the cell block of the undefined battery pack and the SOC-OCV curve of an already-defined cell block and based on a degree of agreement between the resistance capacity product of the cell block of the undefined battery pack and the resistance capacity product of the already-defined cell block.

8. A non-transitory computer-readable recording medium having embodied thereon a battery analysis program comprising computer-implemented modules including:
a module that acquires battery data including i) a voltage of at least one cell block included in a battery pack including cell blocks connected in series, the cell block being comprised of one or more cells connected in parallel and ii) a current flowing in a plurality of cell blocks connected in series;
a module that estimates, for each battery pack, an SOC (State of Charge)-OCV (Open Circuit Voltage) curve of a cell block included in the battery pack, a resistance of the cell block, and a capacity of the cell block, and calculates a resistance capacity product derived from multiplying the resistance of the cell block by the capacity of the cell block; and
a module that identifies a type of the cell included in an undefined battery pack based on a degree of agreement between the SOC-OCV curve of the cell block of the undefined battery pack and the SOC-OCV curve of an already-defined cell block and based on a degree of agreement between the resistance capacity product of the cell block of the undefined battery pack and the resistance capacity product of the already-defined cell block.
